(19) United States
(12) Patent Application Publication
(10) Pub. No.: US 2016/0326664 A1
(43) Pub. Date: Nov. 10, 2016

(54) Treating a Substrate

(71) Applicant: HEWLETT-PACKARD DEVELOPMENT COMPANY, L.P., Houston, TX (US)

(72) Inventors: KUAN-TING WU, TAIPEI CITY (TW); NING CHANG, TAIPEI CITY (TW); YU-CHUAN KANG, TAIPEI CITY (TW)

(21) Appl. No.: 15/030,283

(22) PCT Filed: Jan. 30, 2014
(86) PCT No.: PCT/US2014/013883

§ 371 Date: Apr. 18, 2016

(51) Int. Cl. C25D 13/22; H05K 5/04; C09D 5/24; B41M 5/00; C09D 5/44

(52) U.S. Cl. CPC C25D 13/22; B41M 5/0058; C09D 5/443; C09D 5/4411; C09D 5/24; H05K 5/04

(57) ABSTRACT

A coating of dots is applied to a surface of a metal substrate and an electrophoretic deposition is applied in-between the dots. Either the dots or the electrophoretic deposition are transparent or translucent.

### BACKGROUND

Many electronic devices, such as but not limited to laptop computers, mobile phones, tablet computers etc., have a metal casing. The metal casing may present an attractive metallic appearance which is currently fashionable and aesthetic. However, defects in the metal structure may spoil this effect and can be particularly noticeable with highly reactive metal alloys, or if a transparent, translucent or opaque coating is applied over the metal surface.

### BRIEF DESCRIPTION OF THE DRAWINGS

Examples of the invention will now be described, by way of non-limiting example only, with reference to the accompanying drawings, in which:

FIG. 1 shows a flow diagram of an example method of treating metal substrate;

FIG. 2 (a) shows an example substrate having a metal surface, as seen from above;

FIG. 2 (b) shows the example of FIG. 2(a) after a coating of microdots or nanodots has been applied;

FIG. 2 (c) shows the coated substrate surface of FIG. 2 (b) after an electrophoretic deposition has been applied; and

FIG. 3 shows a cross sectional view of a substrate having a metal surface to which a coating of microdots or nanodots and an electrophoretic deposition have been applied.

### DETAILED DESCRIPTION

The present disclosure proposes applying a coating of microdots or nanodots over a metal surface of a substrate. An electrophoretic deposition is applied over and/or in-between the dots. Either the dots or the electrophoretic deposition is translucent or transparent. Coating the metal surface with microdots or nanodots together with the electrophoretic deposition may provide a metallic appearance, but may help to conceal, or minimize the prominence of, any defects in the metal surface.

In the context of this disclosure a “nanodot” means a dot having a diameter of between 1 and 100 nanometers. A “microdot” means a dot having a diameter of between 0.1 and 100 micrometers. A dot may comprise one particle or a plurality of particles. In one example the dot comprises at least one inorganic or metallic particle adhered to the metal surface by a polymer. The nanodot or microdot may have any shape or size, for example but not limited to circle, triangle, square, oval, trapezoid, rectangular or a combination of the above. In the case that the particle is not circular, the term “diameter” refers to the longest dimension of the particle.

An “electrophoretic deposition” is a coating formed by depositing charged particles suspended in a fluid onto a charged metal surface.

A “substrate” is a piece of solid material having at least one side with a surface area of at least 10 square centimeters. In one example the substrate has a surface area in the range of 0.1-1 square meters and may be formed from a die cast metal or metal alloy.

A method of treating a metal substrate according to the present disclosure will now be described in more detail with reference to the accompanying figures.

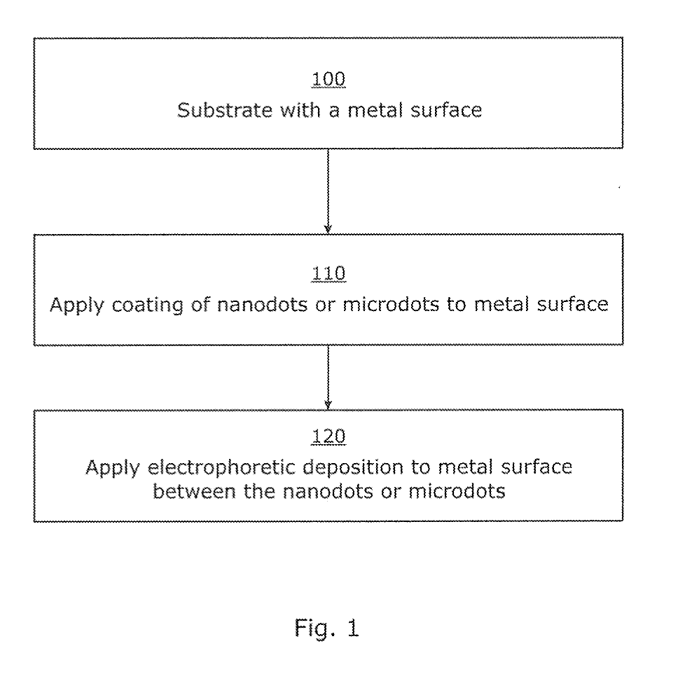

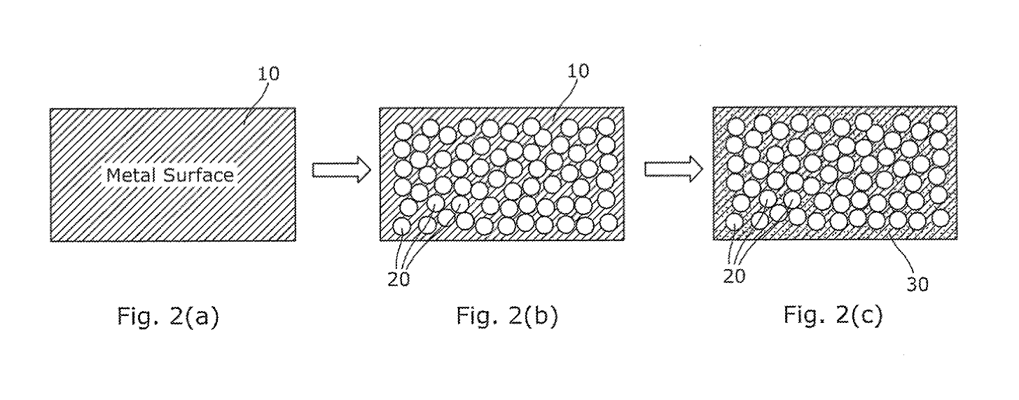

The method starts with a substrate 10 having a metal surface as indicated by block 100 of the flow diagram in FIG. 1 and shown in FIG. 2 (a). The substrate 10 may be formed entirely of metal, or may have several layers of various materials with a top layer formed of a metal. In any case, the substrate 10 has a metal surface. The metal may for example be a light metal or metal alloy such as, but not limited to, Aluminium, Magnesium, Lithium, Titanium, Zinc or one of their alloys. In some examples, the metal surface may be cleaned or scrubbed prior to proceeding to block 110.

At block 110 a plurality of dots are applied to the metal surface. The dots may be microdots and/or nanodots and may have any shape as discussed above. The dots are small and in many cases the individual dots may only be seen under magnification. FIG. 2 (b) shows an example of the layer of microdots or nanodots 20 coated on the electrically conductive metal surface of the substrate 10.

Each microdot or nanodot may comprise one or several metallic or inorganic particles. The particles forming the dots are themselves small and may be microparticles having a diameter less than 100 micrometers, or nanoparticles having a diameter less than 100 nm. The particles may be adhered to the metal surface by a polymer. For example the particles may be suspended in a polymer resin. In some examples the polymer resin may be a fluid when the dots are applied to surface and the resin may subsequently solidify adhering the particles to the metal surface.

The polymer resin may for example comprise polystyrene, polyimide, polyarelene ether, fluorinated polyimide, methylsilsesquioxane, polyethylene, polystyrene silicone, PVC, polyimide, butyl rubber, polyamide, Kapton, Gutta percha, polycarbonate, nylon, styrene-butadiene rubber, polyacrylate, ABS, epoxy, Teflon, a combination of the above or any other suitable materials.

In many cases the polymer itself will form part of the dots and the spaces between the dots will not be coated. That is each dot comprises one or more particles and a polymer, while the spaces between the dots are not coated with polymer. In other cases the polymer may cover the spaces between the dots as well.

The dots 20 may be applied to the metal surface by any suitable method. In one example the dots 20 are printed onto the metal surface, for example by inkjet printing, 3D printing, ink transfer printing, film transfer or screen printing etc.

At block 120 an electrophoretic deposition 30 is deposited over and/or in-between the dots 20. The electrophoretic deposition may for example be deposited by placing the metal substrate in a solution which contains or to which are added positively charged particles. A negative voltage may then be applied to the metal substrate causing the positively charged particles to travel through the solution and deposit themselves on the metal substrate over and/or in-between the coating of microdots or nanodots. In other examples the particles may be negatively charged and the substrate positively charged.

In one example the dots are formed of an electrically insulating material. In this case the electrophoretic deposition is coated between the dots, but not over (on top of) the microdots and nanodots. In another example the dots are formed of electrically conductive materials, in which case the electrophoretic deposition may be coated both on top of and in-between the dots. Having the electrophoretic deposition over the top of the microdot or nanodot surfaces may provide a unique tactile texture.

The electrophoretic deposition may for example comprise a polymer. For example the electrophoretic deposition may comprise polyacrylate, epoxy, or charged conductive polymer materials. In some examples the electrophoretic deposition may contain microparticles or nanoparticles of metallic, or inorganic, materials in addition to the polymer material.

By applying the dots and the electrophoretic deposition to the metal surface, it is possible to provide the surface with a metallic appearance while concealing or reducing the prominence of any defects in the metal surface. Either the dots or the electrophoretic deposition may be formed of a transparent or translucent material. In that way the metallic appearance of the surface may be seen through the nanodots/microdots and/or electrophoretic deposition. The other one of the dots and the electrophoretic deposition may be opaque, such that the opaque nature of that part of the coating helps to conceal any defects. Further, if either the dots or the electrophoretic deposition comprises metallic particles, then this may further enhance the metallic appearance.

In one example the dots are opaque, while the electrophoretic deposition is transparent or translucent. In another example the dots are transparent or translucent while the electrophoretic deposition is opaque. The opaque part of the coating may help to conceal, or minimize the appearance of any defects in the metal surface; while the metal surface shows through the transparent or translucent part of the coating in order to provide a metallic effect.

In one example, the opaque part of the coating may have opacity to visible light of less than 40%. In one example the translucent or transparent part of the coating may have opacity to visible light of at least 50%, in another example at least 80%. The degree of metallic appearance can be controlled by (i) selecting the size and number of the dots per unit area and (ii) selecting the opacity of the dots and/or electrophoretic deposition.

As shown by the block in dotted lines 140, in some implementations a protective coating 40 may be applied over the layer comprising microdots or nanodots 20 and the electrophoretic deposition 30. The protective coating 40 may for example comprise water based or solvent based paints including acrylics, epoxies, alkyds, etc. and may be applied by spray coating or any other suitable method. The protective coating may be resistant to scratches and protects the underlying layers. The protective coating may be transparent or translucent so that the color and/or metallic appearance of the layers below may be seen.

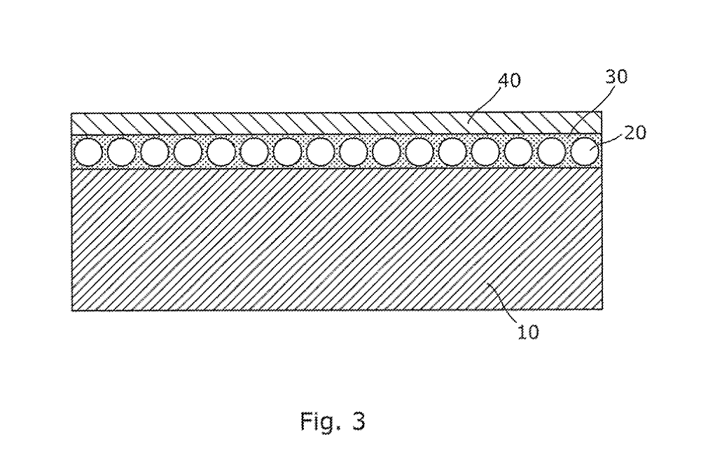

FIG. 3 is a cross sectional view showing a metal substrate 10 to which the microdot or nanodot coating 20, electrophoretic deposition 30 and protective coating 40 have been applied. It can be seen that the electrophoretic deposition 30 extends between the microdots or nanodots. The protective coating 40 extends over both the microdots or nanodots and the electrophoretic deposition.

In other examples there may be no protective coating. Furthermore, in some examples, the electrophoretic deposition may extend over the microdots or nanodots as well as in-between the microdots and nanodots.

The coated metal substrate may be used to form a casing of an electrical device. For example it may be used as the casing of a desktop computer, laptop computer, mobile or smart phone, tablet computer device etc. In some implementations the metal substrate may be cut, molded or shaped into the basic shape and configuration of the desired casing before the coating processes described above. In that situation the various coating layers of FIGS. 1 to 3 may be said to be applied to an electrical device casing. In the context of this disclosure, the term “casing” means any solid structure which acts as an external surface of an electrical device or acts as a case or docking station for the electrical device.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A method of treating a metal substrate comprising applying a coating of dots to a surface of the metal substrate and subsequently applying an electrophoretic deposition in-between the dots; wherein the dots are microdots or nanodots and wherein either the dots or the electrophoretic deposition are transparent or translucent.

2. The method of claim 1 wherein the dots are transparent or translucent and the electrophoretic deposition is opaque.

3. The method of claim wherein the dots are opaque and the electrophoretic deposition is transparent or translucent.

4. The method of claim 1 wherein the dots are electrically conductive and the electrophoretic deposition is over the dots as well as in-between the dots.

5. The method of claim 1 wherein the dots are electrically insulating and the electrophoretic deposition is in-between, but not over the top of the dots.

6. The method of claim 1 wherein the substrate comprises a light metal or a light metal alloy.

7. The method of claim 1 wherein the dots comprise a resin and metallic or inorganic microparticles or nanoparticles in the resin.

8. The method of claim 1 wherein electrophoretic deposition comprises polyacrylate, epoxy, or a charged conductive polymer.

9. The method of claim 1 further comprising applying a protective coating over the dots and the electrophoretic deposition.

10. A method of treating a casing having a metal surface, the method comprising printing dots on the metal surface and then applying an electrophoretic deposition to the metal surface, the dots having diameters of less than 100 micrometers; the dots comprising metallic or inorganic particles and a polymer which adheres the particles to the metal surface.

11. The method of claim 10 wherein one of the dots and the electrophoretic deposition has an opacity to visible light of less than 40% and the other of the dots and the electrophoretic deposition has an opacity to visible light of at least 50%.

12. A casing for an electronic device, the casing comprising a metal layer and a second layer on top of the metal layer, the second layer comprising nanodots or microdots of a first material and an electrophoretic deposition of a second material in-between the microdots or nanodots of the first material; wherein one of the first material and the second material is transparent or translucent.

13. The casing of claim 12 wherein the electrophoretic deposition extends over the microdots or nanodots of the first material.

14. The casing of claim 12 wherein the first material comprises metallic or inorganic material.

15. The casing of claim 12 wherein the second material comprises a polymer.
